(19) United States
(12) Patent Application Publication
(10) Pub. No.: US 2009/0047783 A1
(43) Pub. Date: Feb. 19, 2009

(54) METHOD OF REMOVING UNWANTED PLATED OR CONDUCTIVE MATERIAL FROM A SUBSTRATE, AND METHOD OF ENABLING METALLIZATION OF A SUBSTRATE USING SAME

(76) Inventors: Omar J. Bchir, Phoenix, AZ (US); Houssam Jomaa, Phoenix, AZ (US); Islam A. Salama, Chandler, AZ (US); Yonggang Li, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/838,057

(22) Filed: Aug. 13, 2007

(51) Int. Cl. H01L 21/44; H01L 21/3063

(52) U.S. Cl. 438/687; 205/656; 257/E21.476

(57) ABSTRACT

A method of removing unwanted material from a substrate includes providing a system (600) having an etchant solution (610) with an electrode (620) therein and a current supply (630) connected to the electrode, placing the substrate in the solution and connecting it to the current supply, providing an electric current to the electrode, and altering a polarity of the electric current such that the substrate experiences an anodic polarity for a first time period and a cathodic polarity for a shorter time period. An alternative method includes providing a solution delivery system (1100) having a second etchant solution (1110) with an eductor jet (1140) therein and a recirculation pump connected to the eductor jet, placing the substrate in the second solution, and using the eductor jet to spray the substrate with the second solution. If desired, both methods may be used.

### FIELD OF THE INVENTION

The disclosed embodiments of the invention relate generally to the creation of microelectronic devices, and relate more particularly to the removal of unwanted overplated material between features in microelectronic devices.

### BACKGROUND OF THE INVENTION

The creation of microelectronic devices typically requires the formation of traces or other features in the dielectric material (or another area) of a substrate. Laser projection patterning (LPP), which uses laser ablation to form such features, is one patterning technique that offers advantages for microelectronic applications. Many other patterning techniques also are used. After trenches and vias are ablated or otherwise formed in the dielectric material they must be filled with an electrically conducting material such as copper in order to create electrical interconnects in the substrate. Filling the trenches and vias using standard techniques that combine electroless and electrolytic plating processes requires some degree of overplating above the dielectric surface in order to ensure adequate filling of all traces, lands or planes, and vias on the substrate. The overplated electrically conducting material must then be removed from the substrate in order to electrically isolate the traces and vias from each other and from an integrated circuit.

The overplated material could be removed using chemical mechanical planarization (CMP), which is a standard process for removal of overplated copper in the silicon die fabrication process. However, the use of CMP for substrate manufacture is technically challenging due to manufacturing geometry and may cause problems, including scratching of the dielectric layer, which can create reliability concerns. In addition CMP is generally cost prohibitive in manufacturing organic substrates.

### BRIEF DESCRIPTION OF THE DRAWINGS

The disclosed embodiments will be better understood from a reading of the following detailed description, taken in conjunction with the accompanying figures in the drawings in which:

FIG. 1 is a flowchart illustrating a method of enabling metallization of a substrate according to an embodiment of the invention;

FIGS. 2-5, 7, and 13 are cross-sectional views of a portion of a workpiece at various particular points in a manufacturing process according to an embodiment of the invention;

FIG. 6 is a schematic representation of a system that may be used to remove a portion of a metal layer from a substrate according to an embodiment of the invention;

FIG. 8 is a schematic representation of a current vs. time profile that may be utilized for a PRPE process according to an embodiment of the invention;

FIG. 9 is a schematic representation of a generic differential etching capability of a PRPE process according to an embodiment of the invention;

FIG. 10 is a schematic representation of a concentration profile difference between DC etching and PRPE etching according to an embodiment of the invention;

FIG. 11 is a schematic representation of a system that may be used to remove an additional portion of the metal layer according to an embodiment of the invention; and

FIG. 12 is a perspective view of an eductor jet suitable for use with embodiments of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a method of removing unwanted material from a substrate comprises providing a system including an etchant solution, an electrode in the etchant solution, and a current supply electrically connected to the electrode, placing the substrate in the etchant solution and electrically connecting the substrate to the current supply, providing from the current supply an electric current to the electrode, and altering a polarity of the electric current such that the substrate has an anodic polarity for a first time period and has a cathodic polarity for a second time period. The combination of voltage and time for the anodic vs. cathodic steps must be such that the net effect is to get etching of the panel. This technique may be referred to as Periodic Reverse Pulse Etching (PRPE). Although embodiments of the invention are described herein in terms of their application to a substrate, it should be understood that such embodiments may also apply to and be used in connection with materials such as motherboards, interposers, semiconductor chips, and the like, as well as systems containing some or all of such materials.

In another embodiment of the invention, a method of removing unwanted material from a substrate comprises providing a solution delivery system comprising an etchant solution, an eductor jet in the etchant solution, and a recirculation pump fluidly connected to the eductor jet, placing the substrate in the etchant solution, and using the eductor jet to spray the substrate with the etchant solution. This technique may be referred to as Chemical Planarization with Eductor (CPE).

In another embodiment of the invention, a method of removing unwanted material from a substrate comprises using a PRPE process followed by a CPE process. In this embodiment, a portion of the unwanted material may be removed by the PRPE process, and an additional portion of the unwanted material may be removed by the CPE process. Embodiments of the invention may thus allow substrate planarization without the damage that can occur with more aggressive planarization techniques such as CMP.

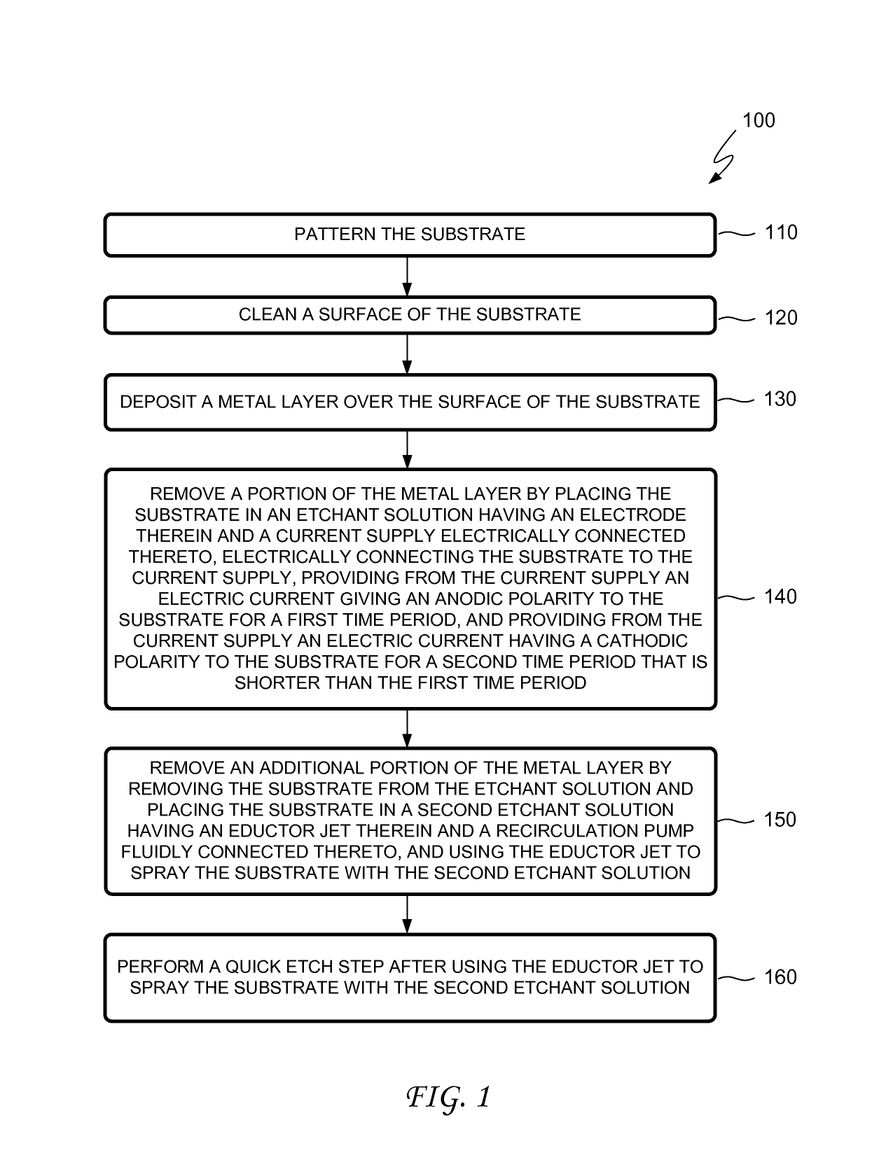

Referring now to the drawings, FIG. 1 is a flowchart illustrating a method 100 of enabling metallization of a substrate according to an embodiment of the invention. A step 110 of method 100 is to pattern the substrate. As an example, the patterning of step 110 may comprise laser projection patterning (LPP), stamping, imprinting by reverse patterning, or another patterning technique.

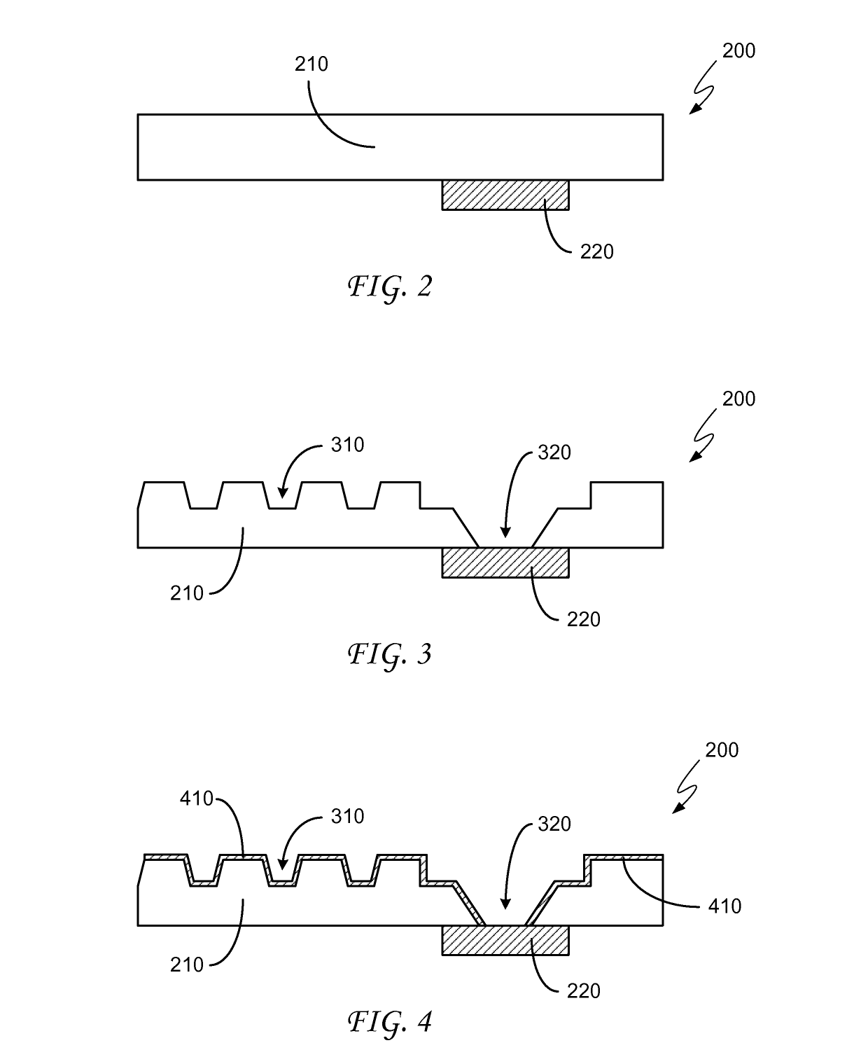

FIG. 2 is a cross-sectional view of a portion of a workpiece 200 at a particular point in a manufacturing process according to an embodiment of the invention. As illustrated in FIG. 2, workpiece 200 comprises a substrate 210 and a pad 220 under substrate 210. As an example, pad 220 can be a copper pad or the like such as is frequently used for substrate metallization. As another example, the substrate referred to in step 110 of method 100 can be similar to substrate 210.

FIG. 3 is a cross-sectional view of a portion of workpiece 200 at a different point in a manufacturing process according to an embodiment of the invention. As an example, FIG. 3 may depict workpiece 200 following the performance of step 110 of method 100. As illustrated in FIG. 3, substrate 210 has been patterned such that it contains trenches 310 and a via 320. In one embodiment, the substrate patterning is performed using laser projection patterning, in which certain regions of substrate 210 are ablated using an excimer laser. As an example, laser projection patterning may provide tighter control of feature width as well as minimize process steps relative to other patterning processes.

A step 120 of method 100 is to clean a surface of the substrate. In one embodiment, step 120 is a desmear process that removes any resin residue from the pattern surface. In another embodiment, step 120 subjects the substrate to alternative treatments such as plasma cleaning with ammonia (NH3), tetrafluoromethane (CF₄) (also known as carbon tetrafluoride), or oxygen or argon plasma or the like, followed by plasma functionalization of the surface by plasma grafting to enable stronger adhesion between the dielectric and copper. Plasma grafting can be accomplished using a series of chemical compounds available on the market today, such as carboxylate moieties on small organic units.

A step 130 of method 100 is to deposit a metal layer over the surface of the substrate. In one embodiment such deposition may be accomplished using a plating technique as known in the art, such as, for example, periodic reverse pulse plating, jet plating with periodic reverse pulse, jet plating with DC current (including horizontal or vertical and any combination of current and flow such that recess is minimized) or the like.

In a particular embodiment, step 130 comprises an electroless plating technique that utilizes palladium (Pd) seeding (either with Pd ion or Pd/Sn (palladium/tin) colloid chemistry) followed by self catalyzed copper (Cu) deposition. In this embodiment electroless Cu will cover the entire surface of the substrate, including protruding edges between adjacent traces. The substrate is then subjected to an electrolytic plating procedure that utilizes DC current, which may be in a batch or continuous mode. This plating technique will insure a maximum Cu thickness variation across the substrate of approximately 5 micrometers (μm). This procedure may leave recesses over the embedded features on the substrate, but since the procedure results in an over plating of copper, these recesses will be of little concern because they will be etched back in the planarization step (described below).

FIG. 4 is a cross-sectional view of a portion of workpiece 200 at a different point in a manufacturing process according to an embodiment of the invention. As an example, FIG. 4 may depict workpiece 200 following the performance or partial performance of step 130 of method 100. As a particular example, FIG. 4 may depict workpiece 200 following an electroless plating process as described above. As illustrated in FIG. 4, a metal layer 410 has been deposited over a surface of substrate 210. As an example, the metal layer referred to in step 130 of method 100 can be similar to metal layer 410.

FIG. 5 is a cross-sectional view of a portion of workpiece 200 at a different point in a manufacturing process according to an embodiment of the invention. As an example, FIG. 5 may depict workpiece 200 following the performance or partial performance (or further performance) of step 130 of method 100. As a particular example, FIG. 5 may depict workpiece 200 following an electrolytic plating procedure as described above.

As illustrated in FIG. 5, a metal layer 510 has been deposited over a surface of substrate 210. For simplicity, the recesses mentioned above are not illustrated in the drawings, but such recesses may in fact be present, as has been discussed. In FIG. 5, metal layer 510 is depicted as having subsumed metal layer 410 (see FIG. 4) such that metal layer 510 occupies the space temporarily occupied earlier by metal layer 410 along with additional space as well. Alternatively, metal layer 510 could be thought of as being a metal layer that is separate and distinct from metal layer 410, in which case both metal layers (410 and 510) would together form a larger metal layer that encompassed both of them. As an example, the metal layer referred to in step 130 of method 100 can be similar to metal layer 510 or to this larger metal layer.

As FIG. 5 shows, metal layer 510 includes overplated material (e.g., copper) that must be removed. It is this overplated material that has been described above as being a candidate for removal using traditional or existing CMP procedures but that would likely be more effectively and/or safely removed using PRPE and/or CPE. These procedures are discussed in more detail in the paragraphs that follow.

A step 140 of method 100 is to remove a portion of the metal layer by placing the substrate in an etchant solution having an electrode therein and a current supply electrically connected thereto, electrically connecting the substrate to the current supply, providing from the current supply an electric current giving an anodic polarity to the substrate for a first time period, and providing from the current supply an electric current having a cathodic polarity to the substrate for a second time period that is shorter than the first time period. As mentioned above, this process may be referred to as a PRPE process.

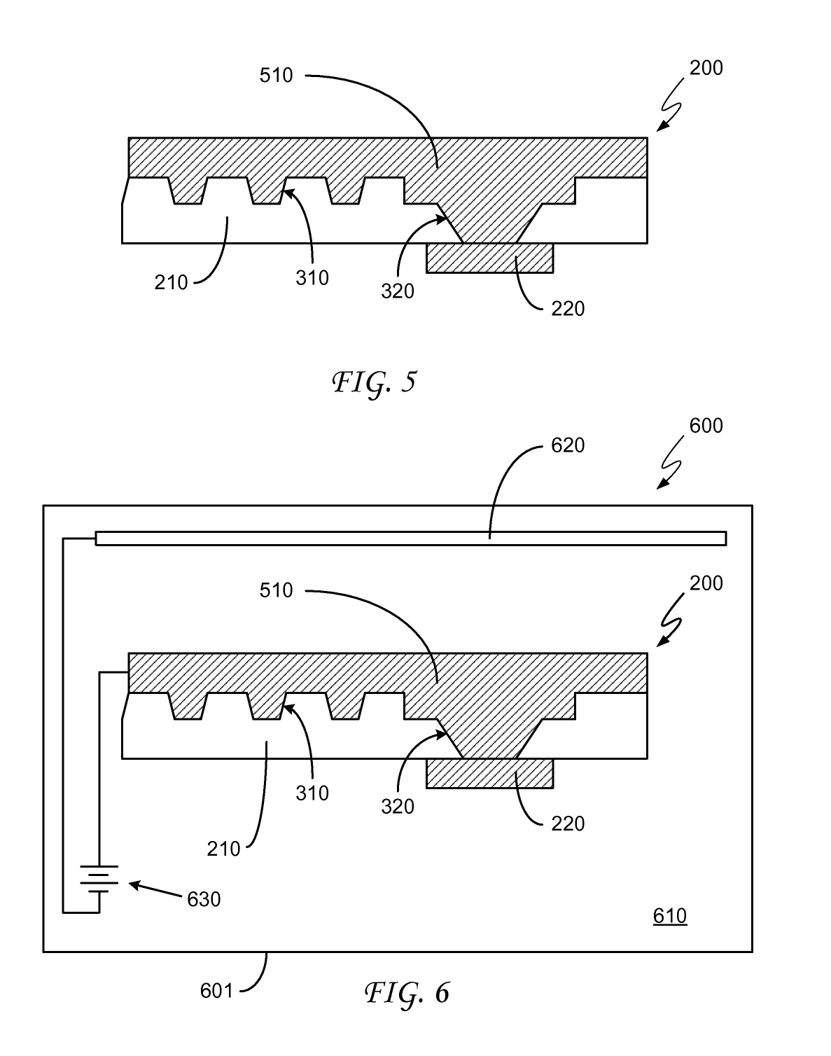

FIG. 6 is a schematic representation of a system 600 that may be used to remove a portion of a metal layer from a substrate according to an embodiment of the invention. As illustrated in FIG. 6, system 600 comprises a container 601 containing an etchant solution 610, an electrode 620, and a current supply 630. As an example, the etchant solution, the electrode, and the current supply mentioned in step 140 of method 100 can be similar to, respectively, etchant solution 610, electrode 620, and current supply 630. The etchant solution chemistry may be adjusted in terms of electrolytes, additives, brighteners, levelers, and other organic species in order to provide the best and most reproducible etching results, as will be recognized by a person of ordinary skill in the art.

As shown, workpiece 200 (which will at various times act as both anode and cathode in system 600, depending on the polarity of the power supply) has been placed in a plating bath (etchant solution 610) in container 601 and electrically connected to current supply 630 and to electrode 620. In the illustrated embodiment, electric current being supplied to workpiece 200 may be controlled by a rectifier (not shown) electrically connected between current supply 630 and a front side of workpiece 200. Another rectifier (also not shown) may if necessary be electrically connected between current supply 630 and a back side of workpiece 200. The rectifiers are capable of alternating the polarity of an electric current delivered to workpiece 200.

For PRPE, the waveform supplied to the rectifiers comprises a current giving the substrate an anodic polarity utilized to enable the stripping of the Cu from the substrate surface (since the substrate is over plated) delivered for a relatively long time (the “first time period” mentioned above), followed by an electrical pulse having a cathodic polarity delivered for a shorter time (the “second time period” mentioned above) in order to reduce the etching speed variation across the substrate surface. The product of current and time (represented by the area under the curve in FIG. 8) must be such that the area is larger for the anodic step, so that net etching occurs. In one embodiment this may be accomplished by making the first time period be longer than the second time period. In a particular embodiment, the first time period is between approximately twice as long and approximately ten times as long as the second time period. In the same or another embodiment, the first time period may be approximately 10 milliseconds (ms) and the second time period may be approximately 1-2 ms.

Since some areas of the surface will have Cu stripped off of them faster than other areas, due to variations in Cu concentration profile build up at the surface, this alteration of current profile is needed to enable consistent etch back across the surface. A determining factor in etching speed for PRPE is physical distance from electrode 620. Overplated Cu that is physically closer to electrode 620 will be etched away at a faster rate than overplated Cu that is farther away. This is due to a higher current concentration at protruding surfaces closer to electrode 620.

The PRPE waveform described above is the inverse of the waveform used with periodic reverse pulse plating (PRPP). PRPP is known to provide a very consistent plating rate across different structures on a substrate by using a rectifier that provides a cathodic current for a considerable period of time, followed by a much smaller reversed (anodic) pulse to remove any over plated Cu from protruding Cu regions. As mentioned above, the inverse waveform used for PRPE will force Cu dissolution from protruding Cu surfaces at a faster rate than on flat or depressed surfaces, allowing the stripping of Cu from different areas on the substrate to be equivalent. PRPP is effective to improve plating uniformity; consequently, it is expected that PRPE will provide equally effective etching uniformity.

Note that factors such as the time or etch pulse, the period/frequency of the wave, the shape of the wave (square vs. sinusoidal), as well as current amplitude all need to be adjusted in order to obtain reproducible and proper Cu stripping off the surface. In many cases, these adjustments would be less time consuming than adjusting the factors associated with CMP. As an example, one or both of rectifiers 641 and 642 may produce a wave having a wave shape, a frequency, a period, and an amplitude, and method 100 may further comprise adjusting one or more of the wave shape, the frequency, the period, the amplitude, the first time period, and the second time period. In one embodiment, adjusting the wave shape comprises causing the rectifier to produce a square wave. In a different embodiment, adjusting the wave shape comprises causing the rectifier to produce a sinusoidal wave.

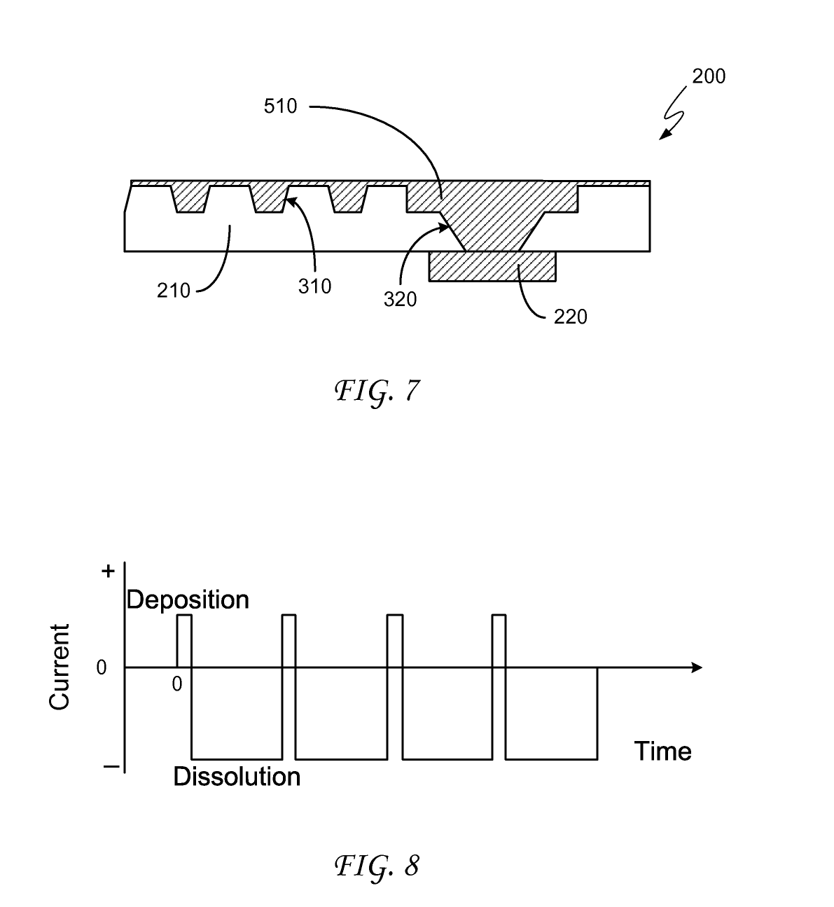

FIG. 7 is a cross sectional view of a portion of workpiece 200 at a different point in a manufacturing process according to an embodiment of the invention. As an example, FIG. 7 may depict workpiece 200 following the performance of step 140 of method 100. As a particular example, FIG. 7 may depict workpiece 200 following a PRPE procedure as described above.

As illustrated in FIG. 7, portions of metal layer 510 have been etched away or otherwise removed from over substrate 210. For simplicity, the recesses mentioned above as possibly being located over embedded features on the substrate are not illustrated in the drawings, but such recesses may in fact be present, as has been discussed. In one embodiment, the portion of metal layer 510 removed in step 140 may be sufficient to bring the surface of metal layer 510 flush with the surface of the underlying surface of substrate 210. In the illustrated embodiment, however, such is not the case, and the surface of metal layer 510 is raised slightly with respect to the surface of substrate 210. Performing the PRPE for a longer period of time would etch away most of the remaining portion of metal layer 510 above the surface of substrate 210, but that longer running time carries with it a risk that electrode 620 may begin to be plated, as well as a risk that a concentration gradient like that associated with DC plating may begin to appear. An alternative method for bringing the surface of metal layer 510 flush with the surface of substrate 210 (a method that avoids the risks just mentioned) is described below as step 150 of method 100.

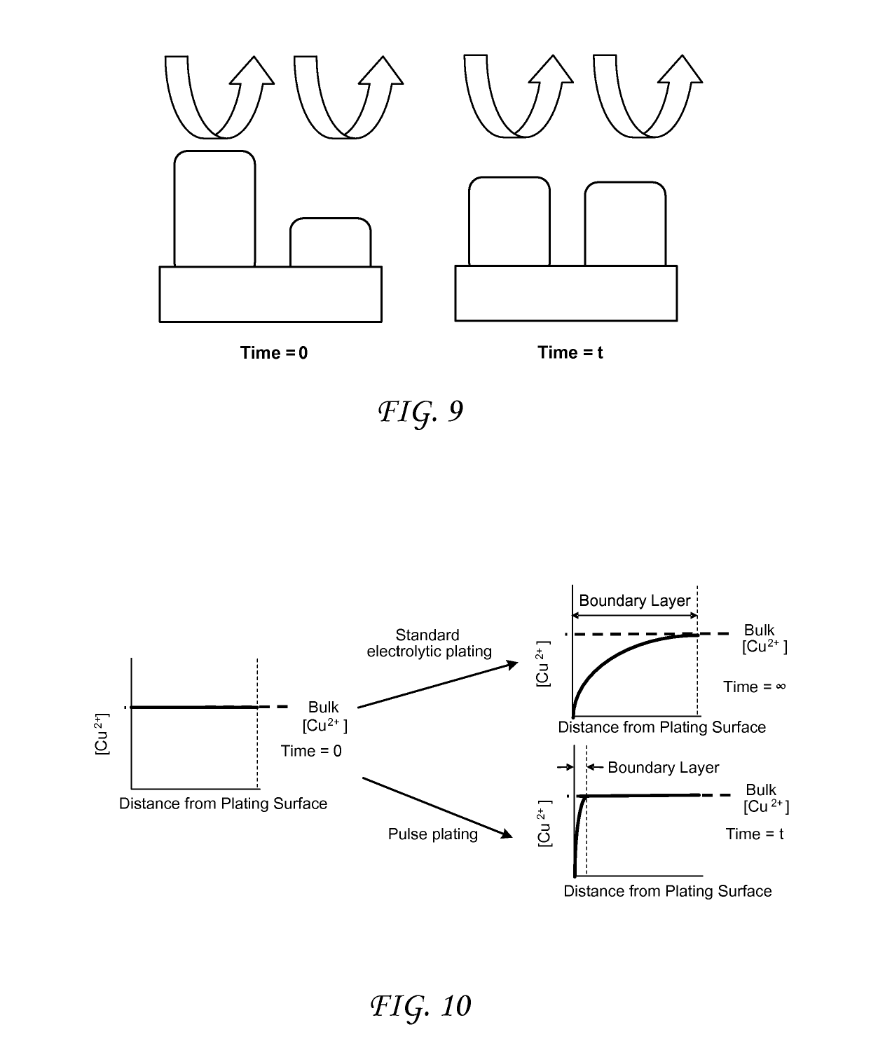

FIGS. 8-10 illustrate various details of a PRPE process according to embodiments of the invention. FIG. 8 is a schematic representation of a square wave produced by a rectifier when PRPE is used. A plot of current vs. time shows the use of a long stripping current followed by a short plating current in a periodic fashion. FIG. 9 is a schematic representation of a generic differential etching capability of PRPE, showing that for PRPE, mass transfer differences favor dissolution at protruding surfaces. For traces of unequal thickness, PRPE will preferentially etch the thicker trace (because of its higher current concentration). FIG. 10 is a schematic representation of a Cu concentration profile difference from the panel surface and into solution bulk as between DC (direct current) plating and PRPP plating. Because PRPP changes the potential at the surface of the panel periodically, any Cu depletion or buildup profile at the panel surface is eliminated as the potential is sequenced back and forth. An analogous principle would apply to PRPE.

A step 150 of method 100 is to remove an additional portion of the metal layer by removing the substrate from the etchant solution and placing the substrate in a second etchant solution having an eductor jet therein and a recirculation pump fluidly connected thereto, and using the eductor jet to spray the substrate with the second etchant solution. As mentioned above, this process may be referred to as a CPE process.

FIG. 11 is a schematic representation of a system 1100 that may be used to remove an additional portion of the metal layer according to an embodiment of the invention. As illustrated in FIG. 11, system 1100 comprises a container 1101 containing an etchant solution 1110, a fluid pipe 1120 (only a portion of which is shown, but which also contains etchant solution 1110) with valves 1121, jet pipes 1130 fluidly connected to fluid pipe 1120, and eductor jets 1140 arranged along jet pipes 1130. As an example, the second etchant solution and the eductor jet mentioned in step 150 of method 100 can be similar to, respectively, etchant solution 1110 and eductorjets 1140.

CPE is based on using jet flow of etching solution onto a workpiece in order to etch back over-plated Cu. In other settings jet flow has proven very effective for Cu plating in minimizing the Cu thickness variation across the workpiece. The flow dynamics with a jet system will force the liquid onto the surface of the workpiece, thus eliminating any byproduct or etchant concentration buildup at the surface of the workpiece, as might occur in the case of regular agitation. By utilizing jet eductors to facilitate solution renewal at the panel surface, etching is expected to be done both quickly and uniformly.

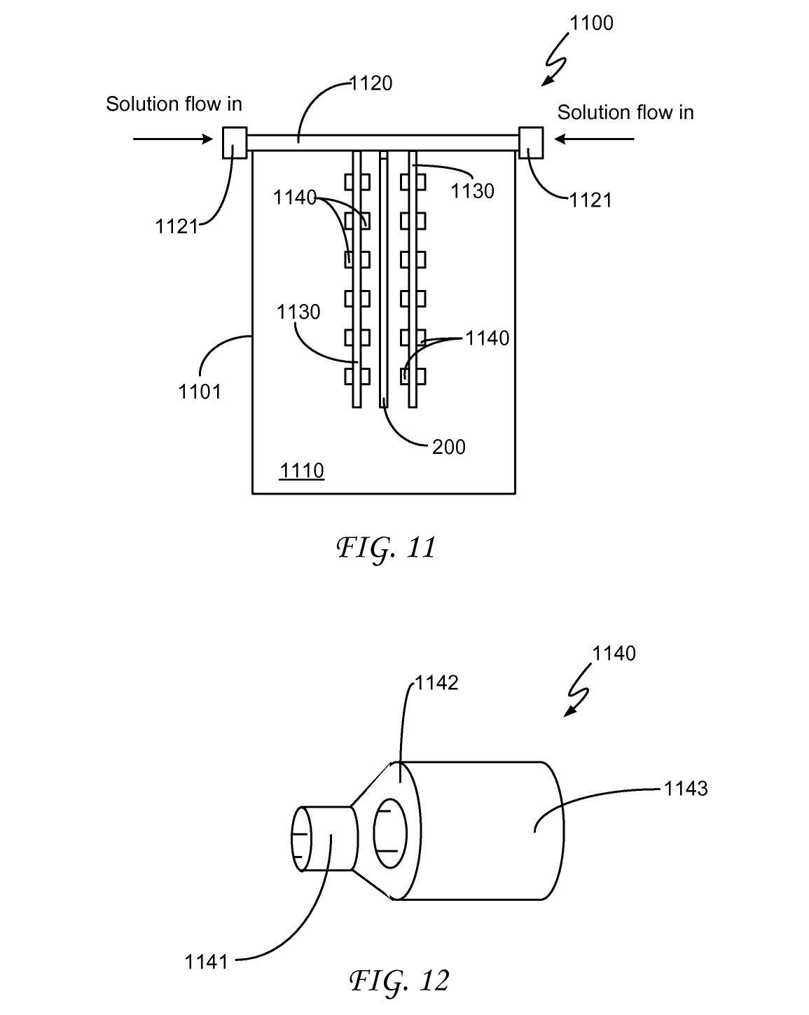

As shown in FIG. 11, workpiece 200 has been placed in a plating bath (etchant solution 1110) in container 1101 between a pair of jet pipes 1130 such that it is located between eductor jet nozzles aimed at the workpiece surface. This will insure proper solution delivery to the workpiece surface. FIG. 12 is a perspective view of eductor jet 1140, where eductor jet 1140 comprises a converging nozzle 1141, a body 1142, and a diffuser 1143. In the illustrated embodiment, system 1100 comprises a plurality of eductor jets 1140, and workpiece 200 has been placed between opposing pairs of such eductor jets.

In operation, the pressure energy of the motive liquid (etchant solution 1110) is converted to velocity energy by the converging nozzle. The high velocity liquid flow then entrains the suction liquid. Complete mixing of the motive and suction is performed in the body and diffuser section. The mixture of liquids is then converted back to an intermediate pressure after passing through the diffuser. The jet nozzle holders include a solution delivery system and piping which would allow solution from the bath to be circulated into the nozzles. The piping on the holders would be connected to a pressurized source of CPE solution (e.g., via fluid pipe 1120 or another branched line from the recirculation pump (not shown)). Solution flow through the nozzles must be optimized in conjunction with etching chemistry to obtain efficient Cu etch back without over/under removal of Cu from the surface. An electronic or mechanical device (not shown) may be added to insure proper control of pressure and solution flow through the nozzle.

A solution chemistry which can be utilized for this process can comprise glycine/hydrogen peroxide (H₂O₂), or some additional additives such as sulfuric acid (H₂SO₄) and ethylenediamine tetraacetic acid (EDTA) to insure dissolution and complexation, respectively. Solution chemistry and solution pressure flow may both need to be adjusted simultaneously.

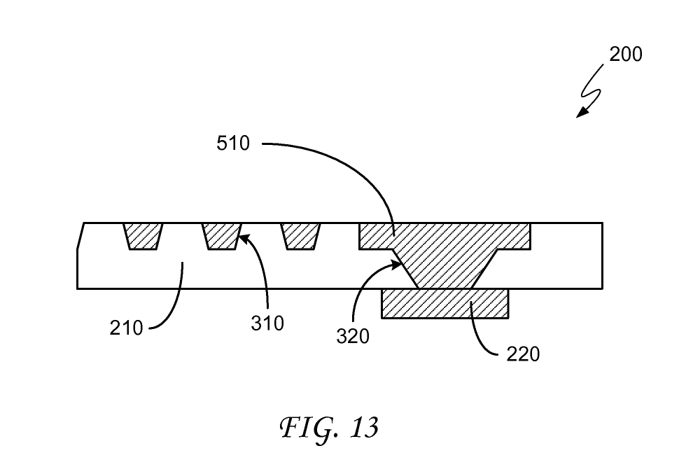

FIG. 13 is a cross sectional view of a portion of workpiece 200 at a different point in a manufacturing process according to an embodiment of the invention. As an example, FIG. 13 may depict workpiece 200 following the performance of step 150 of method 100. As a particular example, FIG. 13 may depict workpiece 200 following a CPE procedure as described above.

As illustrated in FIG. 13, an additional portion of metal layer 510 has been etched away or otherwise removed from over substrate 210. Once again, the recesses mentioned above as possibly being located over embedded features on the substrate are not illustrated in the drawings, but such recesses may in fact be present, as has been discussed. As shown, the portion of metal layer 510 removed in step 150 is sufficient to bring the surface of metal layer 510 flush with the surface of the underlying surface of substrate 210. In one embodiment, workpiece 200 is brought to the stated condition following the performance of steps 140 and 150. In another embodiment, the performance of either of steps 140 and 150 alone may be sufficient to bring workpiece 200 to the stated condition. In yet another embodiment, a further procedure, described below as step 160 of method 100 may be required in order to bring workpiece 200 to the stated condition.

A step 160 of method 100 is to rinse the substrate with water or the like and to perform a quick etch (QE) step after using the eductor jet to spray the substrate with the second etchant solution. In some embodiments step 160 is not necessary and may be omitted. As an example, the QE procedure severs any remaining electrical connections between traces that are to be electrically isolated. In one embodiment, step 160 further comprises subjecting the substrate to a roughening etch or some alternative adhesion promotion technology.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the material removal and metallization enablement methods and related systems discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A method of removing unwanted material from a substrate, the method comprising:
providing a system comprising an etchant solution, an electrode in the etchant solution, and a current supply electrically connected to the electrode;
placing the substrate in the etchant solution and electrically connecting the substrate to the current supply;
providing from the current supply an electric current to the electrode; and
altering a polarity of the electric current such that the electric current has an anodic polarity for a first time period and has a cathodic polarity for a second time period that is shorter than the first time period.

2. The method of claim 1 further comprising:
electrically connecting a rectifier between the current supply and the substrate; and
using the rectifier to alter the polarity of the electric current.

3. The method of claim 2 further comprising:
electrically connecting a second rectifier between the current supply and the substrate; and
using the rectifier to control the polarity of the electric current at a front side of the substrate and using the second rectifier to control the polarity of the electric current at a back side of the substrate.

4. The method of claim 2 wherein:
the first time period is at least approximately twice as long as the second time period.

5. The method of claim 4 wherein:
the first time period is up to approximately ten times longer than the second time period.

6. The method of claim 2 wherein:
the rectifier produces a wave having a wave shape, a frequency, a period, and an amplitude; and
the method further comprises adjusting one or more of the wave shape, the frequency, the period, the amplitude, the first time period, and the second time period.

7. The method of claim 6 wherein:
adjusting the wave shape comprises causing the rectifier to produce a square wave.

8. The method of claim 6 wherein:
adjusting the wave shape comprises causing the rectifier to produce a sinusoidal wave.

9. The method of claim 1 further comprising:
providing a second system comprising a second etchant solution and an eductor jet in the second etchant solution;
removing the substrate from the etchant solution and placing the substrate in the second etchant solution; and
using the eductor jet to spray the substrate with the second etchant solution.

10. The method of claim 9 further comprising:
performing a quick etch step after using the eductor jet to spray the substrate with the second etchant solution.

11. A method of removing unwanted material from a substrate, the method comprising:
providing a solution delivery system comprising an etchant solution, an eductor jet in the etchant solution, and a recirculation pump fluidly connected to the eductor jet;
placing the substrate in the etchant solution; and
using the eductor jet to spray the substrate with the etchant solution.

12. The method of claim 11 wherein:
providing the solution delivery system comprises providing at least a second eductor jet in addition to the eductor jet; and
placing the substrate in the etchant solution comprises placing the substrate between the eductor jet and the second eductor jet.

13. The method of claim 11 wherein:
each of the eductor jet and the second eductor jet comprises a converging nozzle, a body, and a diffuser; and
the converging nozzle converts pressure energy of the etchant solution to velocity energy.

14. The method of claim 13 wherein:
providing the etchant solution comprises providing a solution containing one or more of glycine, hydrogen peroxide, sulfuric acid, and ethylenediamine tetraacetic acid.

15. The method of claim 11 wherein:
providing the solution delivery system further comprises providing a fluid pipe containing a portion of the etchant solution; and
the method further comprises fluidly connecting the eductor jet and the recirculation pump to the fluid pipe.

16. A method of enabling metallization of a substrate, the method comprising:
patterning the substrate;
depositing a metal layer over a surface of the substrate; and
removing a portion of the metal layer by:
placing the substrate in an etchant solution having an electrode therein and a current supply electrically connected thereto;
electrically connecting the substrate to the current supply;
providing from the current supply an electric current having an anodic polarity to the panel for a first time period; and
providing from the current supply an electric current having a cathodic polarity to the substrate for a second time period that is shorter than the first time period.

17. The method of claim 16 further comprising:
removing an additional portion of the metal layer by:
removing the substrate from the etchant solution and placing the substrate in a second etchant solution having an eductor jet therein and a recirculation pump fluidly connected thereto; and
using the eductor jet to spray the substrate with the second etchant solution.

18. The method of claim 17 wherein:
the first time period is between approximately twice as long as the second time period and approximately ten times longer than the second time period.

19. The method of claim 18 further comprising:
electrically connecting a rectifier between the current supply and the substrate; and
using the rectifier to alter a polarity of the electric current from the current supply.

20. The method of claim 19 further comprising:
performing a quick etch step after using the eductor jet to spray the substrate with the second etchant solution.
